(19) United States
(12) Patent Application Publication
(10) Pub. No.: US 2009/0197186 A1
(43) Pub. Date: Aug. 6, 2009

(54) OPTICAL DEVICES RESPONSIVE TO BLUE LASER AND METHOD OF MODULATING LIGHT

(75) Inventors: Tao Gu, San Diego, CA (US); Peng Wang, San Diego, CA (US); Weiping Lin, Carlsbad, CA (US); Donald Flores, San Diego, CA (US); Michiharu Yamamoto, Carlsbad, CA (US)

Correspondence Address: KNOBBE MARTENS OLSON & BEAR LLP, 2040 MAIN STREET, FOURTEENTH FLOOR, IRVINE, CA, 92614, US

(73) Assignee: NITTO DENKO CORPORATION, Osaka (JP)

(21) Appl. No.: 12/361,841

(22) Filed: Jan. 29, 2009

Related U.S. Application Data
(60) Provisional application No. 61/026,412, filed on Feb. 5, 2008.

(51) Int. Cl. G03F 7/004; C08F 118/02

(52) U.S. Cl. 430/2; 526/312

(57) ABSTRACT

An optical device comprising a photorefractive composition configured to be photorefractive upon irradiation by a blue laser. The photorefractive composition comprises a polymer comprising a repeating unit including at least a moiety selected from the group consisting of the formulas (Ia), (Ib) and (Ic), as defined herein.

### CROSS-REFERENCE TO RELATED APPLICATIONS

This application claims priority U.S. Provisional Patent Application No. 61,026,412, entitled “Optical Devices Responsive to Blue Laser and Method of Modulating light,” filed on Feb. 5, 2008, the contents of which are incorporated by reference in their entirety.

### BACKGROUND OF THE INVENTION

1. Field of the Invention

The invention relates to a photorefractive composition comprising a polymer that is configured to be photorefractive upon irradiation by a blue laser. More particularly, the polymer comprises a repeating unit including a moiety selected from the group consisting of the carbazole moiety, tetraphenyl diaminobiphenyl moiety, and triphenylamine moiety. Additionally, the composition can be configured to be photorefractive upon irradiation by incorporating a blue laser sensitive chromophore. Furthermore, the invention relates to a method for modulating light using the photorefractive composition that is irradiated by a blue laser. The composition can be used for holographic data storage or image recording materials and device area.

2. Description of the Related Art

Photorefractivity is a phenomenon in which the refractive index of a material can be altered by changing the electric field within the material, such as by laser beam irradiation. The change of the refractive index typically involves: (1) charge generation by laser irradiation, (2) charge transport, resulting in the separation of positive and negative charges, (3) trapping of one type of charge (charge delocalization), (4) formation of a non-uniform internal electric field (space-charge field) as a result of charge delocalization, and (5) a refractive index change induced by the non-uniform electric field. Good photorefractive properties are typically observed in materials that combine good charge generation, charge transport or photoconductivity and electro-optical activity. Photorefractive materials have many promising applications, such as high-density optical data storage, dynamic holography, optical image processing, phase conjugated mirrors, optical computing, parallel optical logic, and pattern recognition. Particularly, long lasting grating behavior can contribute significantly for high-density optical data storage or holographic display applications.

Originally, the photorefractive effect was found in a variety of inorganic electro-optical (EO) crystals, such as LiNbO₃. In these materials, the mechanism of a refractive index modulation by the internal space-charge field is based on a linear electro-optical effect.

In 1990 and 1991, the first organic photorefractive crystal and polymeric photorefractive materials were discovered and reported. Such materials are disclosed, for example, in U.S. Pat. No. 5,064,264, the contents of which are hereby incorporated by reference in their entirety. Organic photorefractive materials offer many advantages over the original inorganic photorefractive crystals, such as large optical nonlinearities, low dielectric constants, low cost, lightweight, structural flexibility, and ease of device fabrication. Other important characteristics that may be desirable depending on the application include sufficiently long shelf life, optical quality, and thermal stability. These kinds of active organic polymers are emerging as key materials for advanced information and telecommunication technology.

In recent years, efforts have been made to optimize the properties of organic, and particularly polymeric, photorefractive materials. Various studies have been done to examine the selection and combination of the components that give rise to each of these features. The photoconductive capability is frequently provided by incorporating materials containing carbazole groups. Phenyl amine groups can also be used for the charge transport part of the material.

Non-linear optical ability is generally provided by including chromophore compounds, such as an azo-type dye that can absorb photon radiation. The chromophore may also provide adequate charge generation. Alternatively, a material known as a sensitizer may be added to provide or boost the mobile charge for photorefractivity to occur.

The photorefractive composition may be made by mixing molecular components that provide desirable individual properties into a host polymer matrix. However, most of previously prepared compositions failed to show good photorefractivity performances, (e.g., high diffraction efficiency, fast response time and long-term stability). Efforts have been made, therefore, to provide compositions which show high diffraction efficiency, fast response time and long stability.

U.S. Pat. Nos. 6,653,421 B1 and 6,610,809 B1, the contents of which are both hereby incorporated by reference in their entirety, disclose (meth)acrylate-based polymers and copolymer based materials which showed high diffraction efficiency, fast response time, and long-term phase stability. The materials show fast response times of less than 30 msec and diffraction efficiency of higher than 50%, along with no phase separation for at least two or three months.

Also, US 2004/0043301, the contents of which are hereby incorporated by reference in their entirety, discloses a data storage medium, comprising a recording layer containing molecules having charge transport characteristics, molecules having nonlinear optical characteristics, and optical functional molecules whose stereostructure is changed depending on a light irradiation, and a pair of transparent ohmic electrodes sandwiching the recording layer. The conductivity of the data storage medium is lowered by the light irradiation. However, the diffraction efficiency immediately after the recording was found to be 1.0%. This device is ineffective for actual applications.

### SUMMARY OF THE INVENTION

There remains a need for photorefractive compositions that combine all of the above-mentioned attributes that are configured to be photorefractive upon irradiation with a blue laser. The present invention describes compositions and methods of using thereof, where grating signals can be written and held after several minutes, or longer, for data or image storage purpose. The organic based materials and holographic medium developed by the inventors show fast response times and good diffraction efficiencies to blue lasers. Furthermore, grating signals can also be rewritten into the compositions after initial exposure. The availability of such materials that are sensitive to a blue continuous wave (CW) laser system can be greatly advantageous and useful for industrial application purpose and image storage purposes.

Some embodiments of this invention provide a photorefractive composition responsive to a blue laser, wherein the photorefractive composition comprises a hole-transfer type polymer which exhibits fast response time, high diffraction efficiency, and good phase stability. More specifically, the polymer may comprise at least a repeating unit including a moiety selected from the group consisting of the carbazole moiety, tetraphenyl diaminobiphenyl moiety, and triphenylamine moiety. In some embodiment, the composition can be used for holographic data storage, as image recording materials, and in optical devices.

In an embodiment, a photorefractive composition is provided that is configured to be photorefractive upon irradiation by a blue laser, wherein the photorefractive composition comprises a polymer, wherein the polymer comprises a repeating unit that includes at least one moiety selected from the group consisting of the following formulas:

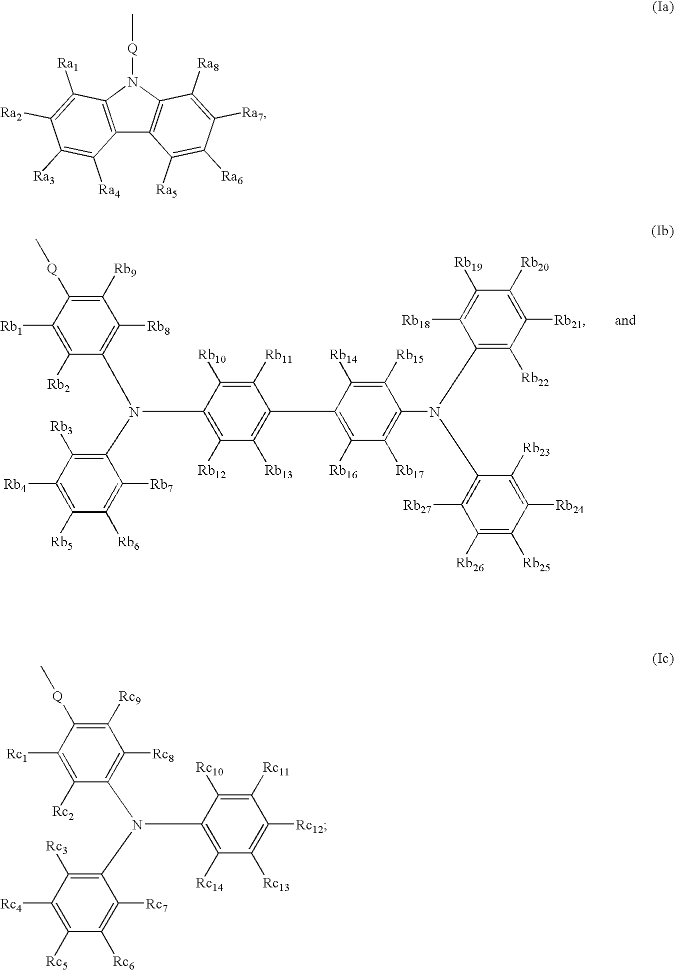

wherein each Q in formulas (Ia), (Ib) and (Ic) independently represents an alkylene or a heteroalkylene, Ra₁-Ra₈, Rb₁-Rb₂₇ and Rc₁-Rc₁₄ in (Ia), (Ib), and (Ic) are each independently selected from the group consisting of hydrogen, C₁-C₁₀ alkyl, and C₄-C₁₀ aryl, wherein the C₁-C₁₀ alkyl may be linear or branched.

In some embodiments, the polymer further comprises a second repeating unit that includes a moiety represented by the following formula:

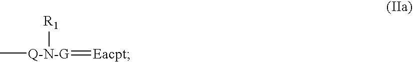

wherein Q in formula (IIa) represents an alkylene group or a heteroalkylene group, R₁ in formula (IIa) is selected from the group consisting of hydrogen, linear C₁-C₁₀ alkyl, branched C₁-C₁₀ alkyl and C₄-C₁₀ aryl, G in formula (IIa) is a n-conjugated group and Eacpt in formula (Ia) is an electron acceptor group.

The composition can be configured to be photorefractive upon irradiation of a blue laser by incorporation of an ingredient that provides additional non-linear optical functionality into the photorefractive composition. For example, the composition can be configured to be photorefractive upon irradiation of a blue laser by incorporation of a chormophore. The chormophore can be added into the composition as a mixture with the polymer and/or be directly bonded to the polymer, e.g., by covalent or other bonding. In some embodiments, the photorefractive composition further comprises an ingredient that provides additional non-linear optical functionality represented by the formula (IIb): D-B-A, wherein the ingredient that provides additional non-linear optical functionality is sensitive to a blue laser. In an embodiment, D in formula (IIb) is an electron donor group, B in formula (IIb) is a π-conjugated group, and A in formula (IIb) is an electron acceptor group.

In some embodiment, the composition further comprises a plasticizer and/or sensitizer. In an embodiment, the plasticizer is selected from N-alkyl carbazole and triphenylamine derivatives.

Some embodiments also provide a method of modulating light comprising the steps of providing a photorefractive composition comprising a polymer, wherein the polymer comprises a repeating unit that includes a moiety selected from the group consisting of (Ia), (Ib), and (Ic) as described above; and irradiating the photorefractive composition with a blue laser to thereby modulate a photorefractive property of the composition.

The compositions described herein have great utility in a variety of optical applications, including holographic storage, optical correlation, phase conjugation, non-destructive evaluation, and imaging.

### BRIEF DESCRIPTION OF THE DRAWINGS

FIG. 1 is a schematic depiction illustrating a hologram recording system with a photorefractive composition.

### DETAILED DESCRIPTION OF THE INVENTION

While previously described compositions respond favorably to red laser at 633 nm wavelength or to green laser at 532 nm wavelength, respectively, their chemical and optical properties are incompatible with the transmittance of blue light. The compositions described in the present invention exhibit photorefractive behavior to blue laser for the first time. Some embodiments provide an optical device comprising a photorefractive composition. The photorefractive composition that comprises a polymer becomes photorefractive upon irradiation by a blue laser. In some embodiments, the photorefractive composition may further comprise an ingredient that provides additional non-linear optical functionality, such as a chromophore, wherein the ingredient that provides additional non-linear optical functionality contains an electron donor group, an electron acceptor group, and a π-conjugated group connecting the electron donor and the electron acceptor groups. In an embodiment, the ingredient that provides additional non-linear optical functionality is sensitive to a blue laser. In some embodiments, the ingredient that provides additional non-linear optical functionality can be attached to the polymer backbone in side chains. In some embodiments, the ingredient that provides additional non-linear optical functionality can be incorporated into the photorefractive composition as a stand-alone compound. In some embodiments, the photorefractive composition may further comprise a plasticizer and/or a sensitizer.

Some embodiments provide an optical device comprising a photorefractive composition responsive to irradiation by a blue laser. In some embodiments, the composition can be made photorefractive upon irradiation by a blue continuous wave (CW) laser. The composition that comprises a polymer exhibits photorefractive behavior upon irradiation by a blue laser, wherein the polymer comprises a repeating unit that include at least one moiety selected from the group consisting of the carbazole moiety (represented by formula Ia), tetraphenyl diaminobiphenyl moiety (represented by the formula Ib), and triphenylamine moiety (represented by the formula Ic). These moieties are represented by the following formulas:

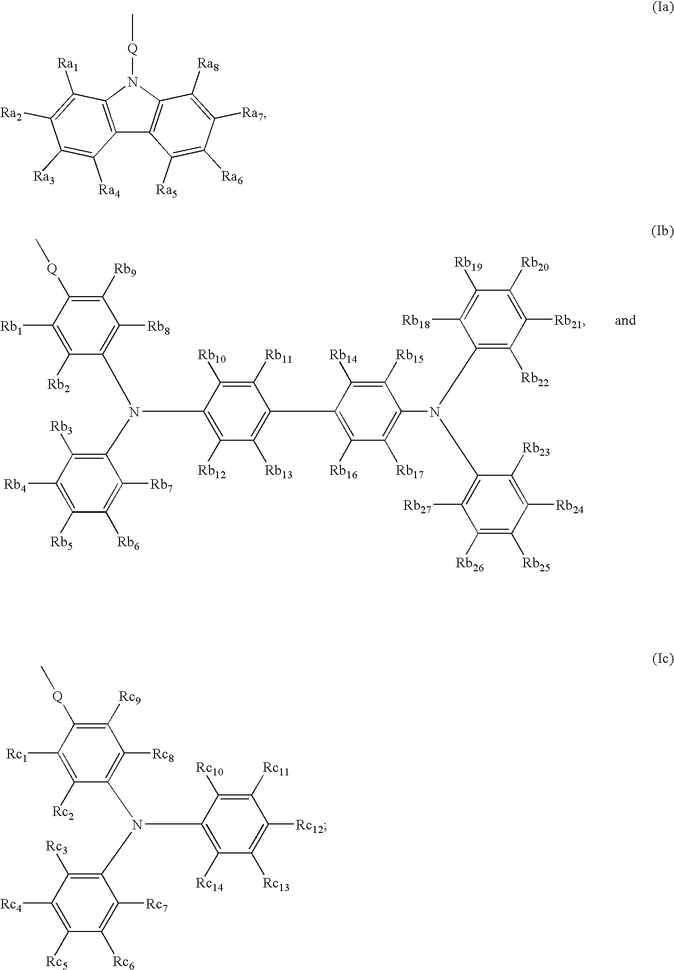

wherein each Q in formulas (Ia), (Ib) and (Ic) independently represents an alkylene group or a heteroalkylene group; Ra₁-Ra₈, Rb₁-Rb₂₇ and Rc₁-Rc₁₄ in formulas (Ia), (Ib), and (Ic) are each independently selected from the group consisting of hydrogen, C₁-C₁₀ alkyl, and C₄-C₁₀ aryl; wherein the alkyl may be linear or branched. The heteroalkylene group can comprise one or more heteroatoms. Any heteroatom or combination of heteroatoms can be used, including O, N, S, and any combination thereof.

In some embodiments, at least one of formulas (Ia), (Ib) and (Ic) may be polymerized or copolymerized to form a charge transport component of a photorefractive composition. In some embodiments, for example, each moiety alone may polymerize to form a photorefractive polymer. In some embodiments, for example, two or more of the moieties may also be co-polymerized to form a photorefractive polymer. The polymer or copolymer formed by these moieties has the charge transport ability.

Many polymer backbone, including but not limited to, polyurethane, epoxy polymers, polystyrene, polyether, polyester, polyamide, polyimide, polysiloxane, and polyacrylate, with the appropriate side chains attached, can be used to make the polymer matrices of the photorefractive composition. Some embodiments contain backbone units based on acrylates or styrene, and some of preferred backbone units are formed from acrylate-based monomers, and some are formed from methacrylate monomers. It is believed that the first polymeric materials to include photoconductive functionality in the polymer itself were the polyvinyl carbazole materials developed at the University of Arizona. However, these polyvinyl carbazole polymers tend to become viscous and sticky when subjected to the heat-processing methods typically used to form the polymer into films or other shapes for use in photorefractive devices.

The (meth)acrylate-based and acrylate-based polymers used in embodiments described herein have much better thermal and mechanical properties. In other words, they provide better workability during processing by injection-molding or extrusion, especially when the polymers are prepared by radical polymerization. Some embodiments provide a composition comprising a photorefractive polymer that is activated upon irradiation by a blue laser, wherein the photorefractive polymer comprises a repeating unit selected from the group consisting of the following formulas:

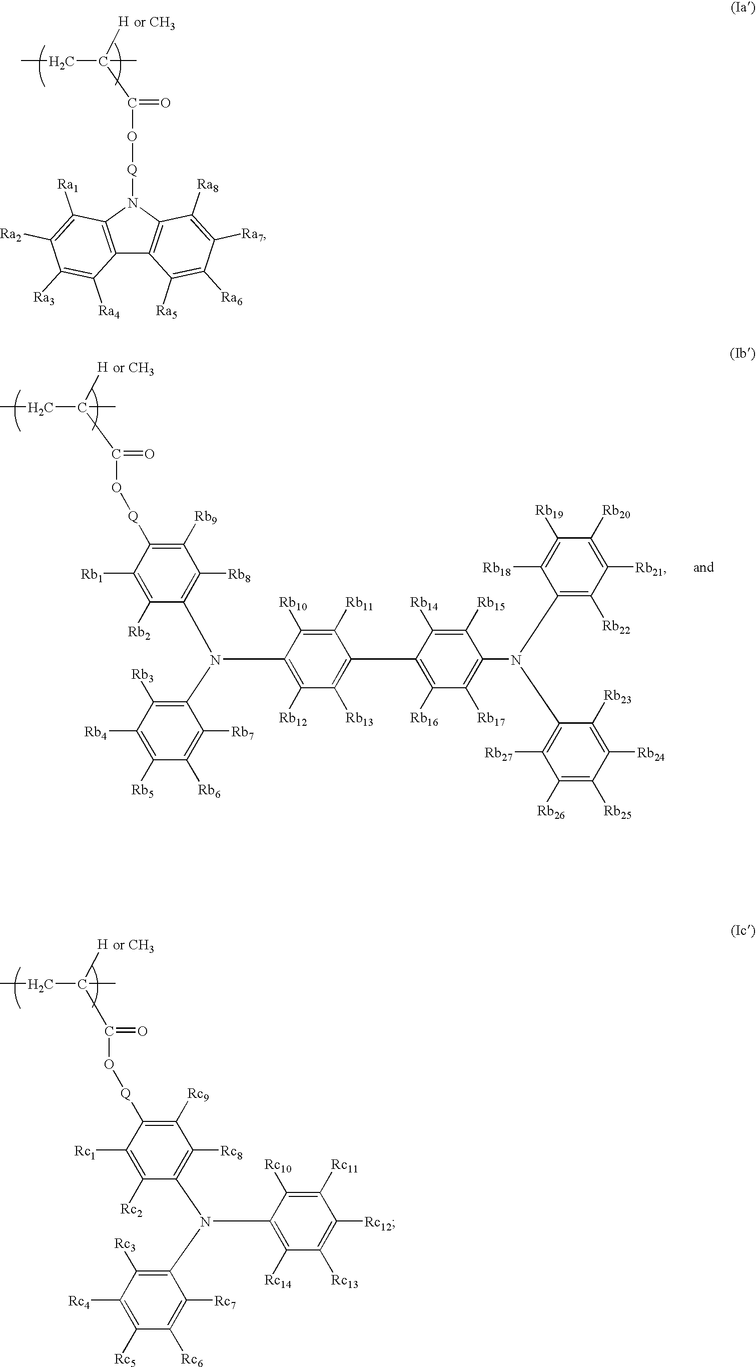

wherein each Q in formulas (Ia′), (Ib′) and (Ic′) independently represents an alkylene group or a heteroalkylene group; Ra₁-Ra₈, Rb₁-Rb₂₇ and Rc₁-Rc₁₄ in formulas (Ia′), (Ib′) and (Ic′) are each independently selected from the group consisting of hydrogen, C₁-C₁₀ alkyl, and C₄-C₁₀ aryl; wherein the alkyl can be either branched or linear, and the heteroalkylene group has one or more heteroatoms selected from S, N, or O.

In some embodiments, at least one of formulas (Ia′), (Ib′) and (Ic′) can also be polymerized or copolymerized to form a photorefractive polymer that provides charge transport ability. In some embodiments, monomers comprising a phenyl amine derivative can be copolymerized to form the charge transport component as well. Non-limiting examples of such monomers are carbazolylpropyl (meth)acrylate monomer; 4-(N,N-diphenylamino)-phenylpropyl (meth)acrylate; N-[(meth)acroyloxypropylphenyl]-N,N′,N′-triphenyl-(1,1′-biphenyl)-4,4′-diamine; N-[(meth)acroyloxypropylphenyl]-N′-phenyl-N,N′-di(4-methylphenyl)-(1,1′-biphenyl)-4,4′-diamine; and N-[(meth)acroyloxypropylphenyl]-N′-phenyl-N,N′-di(4-buthoxyphenyl)-(1,1′-biphenyl)-4,4′-diamine. These monomers can be used by themselves or as a mixture of two or more monomers.

In some embodiments, the photorefractive composition further comprises another component that has the non-linear optical functionality. Moieties or chromophores with non-linear optical functionality may be incorporated into the polymer matrix as an additive to the composition or as side chains attached to monomers to be copolymerized. While moieties or chromophores can be any group known in the art to provide non-linear optical capability, it is preferable to include the chromophores described herein that are blue laser sensitive.

In some embodiments, the photorefractive composition may comprise additional polymer having one or more non-linear optical moiety. In some embodiments, the non-linear optical moiety may be presented as a side chain on a polymer backbone that allows copolymerization with polymers with charge transport moieties. In some embodiments, the photorefractive polymer further comprises a second repeating unit represented by the following formula:

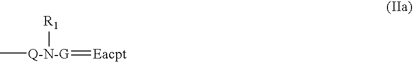

wherein Q in formula (IIa) represents an alkylene group or a heteroalkylene group, the heteroalkylene group has one or more heteroatoms selected from S or O; R₁ in formula (IIa) is selected from the group consisting of hydrogen, linear and branched C₁-C₁₀ alkyl, and C₄-C₁₀ aryl; G in formula (IIa) is π-conjugated group; and Eacpt in formula (IIa) is an electron acceptor group. In some embodiments, R₁ in formula (IIa) is an alkyl group selected from methyl, ethyl, propyl, butyl, pentyl and hexyl. In some embodiments, Q in formula (Ia) is an alkylene group represented by (CH₂)ₚ where p is between about 2 and about 6. In some embodiments, Q in formula (IIa) is selected from the group consisting of ethylene, propylene, butylene, pentylene, hexylene, and heptylene.

In some embodiments, the polymer comprises a repeating unit represented by the following formula:

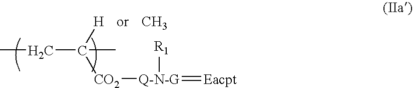

wherein Q in formula (IIa′) represents an alkylene group or a heteroalkylene group, the heteroalkylene group has one or more heteroatom such as S or O; R₁ in formula (IIa′) is selected from the group consisting of hydrogen, linear and branched C₁-C₁₀ alkyl, and C₄-C₁₀ aryl; G in formula (IIa′) is a π-conjugated group and Eacpt in formula (IIa′) is an electron acceptor group. In some embodiments, R₁ in formula (IIa′) is an alkyl group selected from methyl, ethyl, propyl, butyl, pentyl and hexyl. In some embodiments, Q in formula (IIa′) is an alkylene group represented by (CH₂)ₚ where p is between about 2 and about 6. In some embodiments, Q in formula (IIa′) is selected from the group consisting of ethylene, propylene, butylene, pentylene, hexylene, and heptylene.

The term “π-conjugated group” refers to a molecular fragment that contains π-conjugated bonds. The π-conjugated bonds refer to covalent bonds between atoms that have 6 bonds and π bonds formed between two atoms by overlapping of atomic orbits (s+p hybrid atomic orbits for a bonds and p atomic orbits for a bonds). In some embodiments, G in formulas (IIa) and (IIa′) is independently represented by a formula selected from the following:

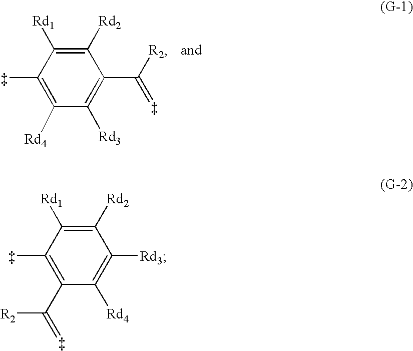

wherein Rd₁-Rd₄ in (G-1) and (G-2) are each independently selected from the group consisting of hydrogen, linear and branched C₁-C₁₀ alkyl, C₄-C₁₀ aryl, and halogen and R₂ in (G-1) and (G-2) is independently selected from the group consisting of hydrogen, linear and branched C₁-C₁₀ alkyl, and C₄-C₁₀ aryl.

The term “electron acceptor group” refers to a group of atoms with a high electron affinity that can be bonded to a π-conjugated group. Exemplary acceptors, in order of increasing strength, are: C(O)NR²<C(O)NHR<C(O)NH₂<C(O)OR<C(O)OH<C(O)R<C(O)H<CN<S(O)₂R<NO₂, wherein each R in these electron acceptors may independently be, for example, hydrogen, linear and branched C₁-C₁₀ alkyl, and C₄-C₁₀ aryl. As shown in U.S. Pat. No. 6,267,913, examples of electron acceptor groups include:

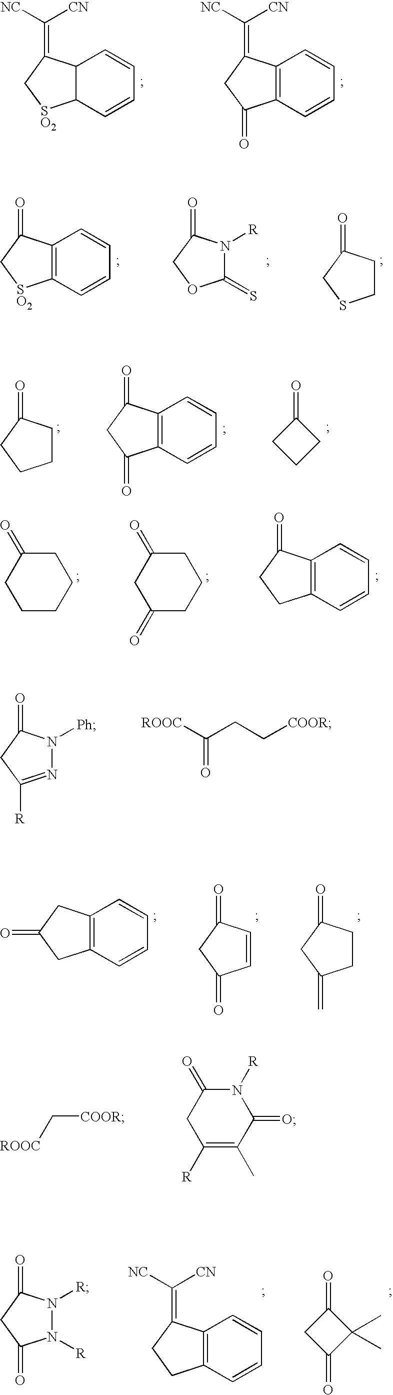

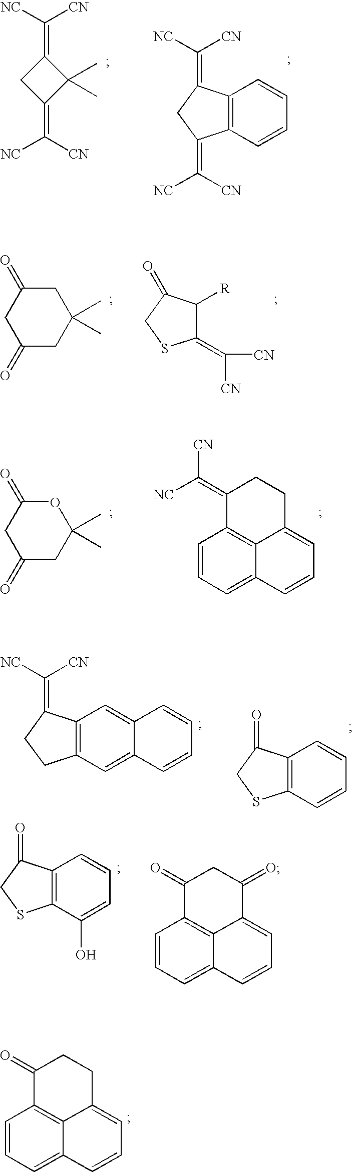

wherein R is selected from the group consisting of hydrogen, linear and branched C₁-C₁₀ alkyl, and C₄-C₁₀ aryl. The symbol “‡” in a chemical structure specifies an atom of attachment to another chemical group and indicates that the structure is missing a hydrogen that would normally be implied by the structure in the absence of the “‡”

In some embodiments, Eacpt in formulas (IIa) and (IIa′) may be independently represented by a formula selected from the group consisting of the following:

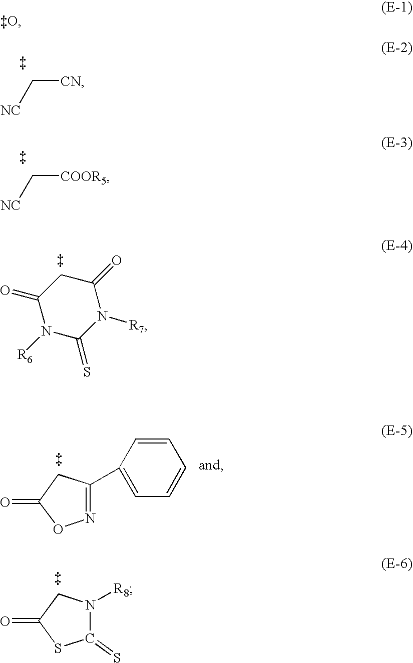

wherein R₅, R₆, R₇ and R₈ in formulas (E-3), (E-4) and (E-6) are each independently selected from the group consisting of hydrogen, linear and branched C₁-C₁₀ alkyl, and C₄-C₁₀ aryl.

To prepare the non-linear optical component containing copolymer, monomers that have side-chain groups possessing non-linear-optical ability may be used. Non-limiting examples of such monomers include:

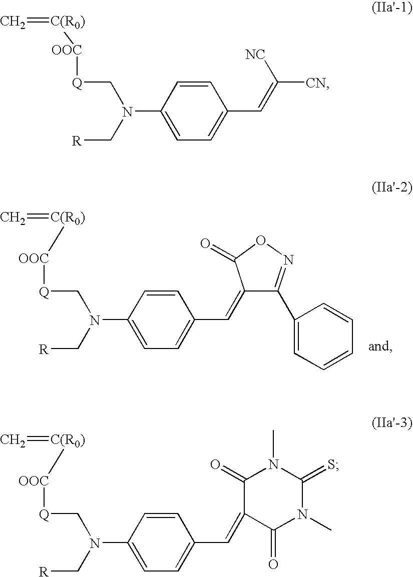

wherein each Q in the monomers above independently represent an alkylene group or a heteroalkylene group, the heteroalkylene group has one or more heteroatoms such as O and S; each R₀ in the monomers above is independently selected from hydrogen or methyl; and each R in the monomers above is independently selected from linear and branched C₁-C₁₀ alkyl. In some embodiments, Q in the monomers above may be an alkylene group represented by (CH₂)ₚ where p is in the range of about 2 to about 6. In some embodiments, each R in the monomers above may be independently selected from the group consisting methyl, ethyl and propyl. Each R₀ in the monomers above may be independently H or CH₃.

In some embodiments, monomers comprising a chromorphore, can also be used to prepare the non-linear optical component containing polymer. Non-limiting examples of monomers including a chromophore group as the non-linear optical component include N-ethyl, N-4-dicyanomethylidenyl acrylate and N-ethyl, N-4-dicyanomethylidenyl-3,4,5,6,10-pentahydronaphtylpentyl acrylate.

The polymers described herein may be prepared in various ways, e.g., by polymerization of the corresponding monomers or precursors thereof. Polymerization may be carried out by methods known to a skilled artisan, as informed by the guidance provided herein. In some embodiments, radical polymerization using an azo-type initiator, such as AIBN (azoisobutyl nitrile), may be carried out. The radical polymerization technique makes it possible to prepare random or block copolymers comprising both charge transport and non-linear optical groups. Further, by following the techniques described herein, it is possible to prepare such materials with exceptionally good properties, such as photoconductivity, response time and diffraction efficiency. In an embodiment of a radical polymerization method, the polymerization catalysis is generally used in an amount of from 0.01 to 5 mole % or from 0.1 to 1 mole % per mole of the total polymerizable monomers.

In some embodiments, radical polymerization can be carried out under inert gas (e.g., nitrogen, argon, or helium) and/or in the presence of a solvent (e.g., ethyl acetate, tetrahydrofuran, butyl acetate, toluene or xylene). Polymerization may be carried out under a pressure from 1 to 50 Kgf/cm² or from 1 to 5 Kgf/cm². In some embodiments, the concentration of total polymerizable monomer in a solvent may be about 0.99% to about 50% by weight, preferably about 2% to about 9.1% by weight. The polymerization may be carried out at a temperature of about 50° C. to about 100° C., and may be allowed to continue for about 1 to about 100 hours, depending on the desired final molecular weight, polymerization temperature, and taking into account the polymerization rate.

Some embodiments provide a polymerization method involving the use of a precursor monomer with a functional group for non-linear optical ability for preparing the copolymers. The precursor may be represented by the following formula:

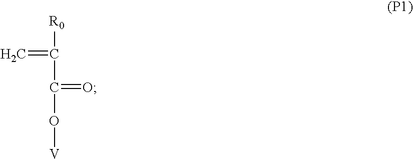

wherein R₀ in (P1) is hydrogen or methyl, and V in (P1) is a group selected from the formulas (V-1) and (V-2):

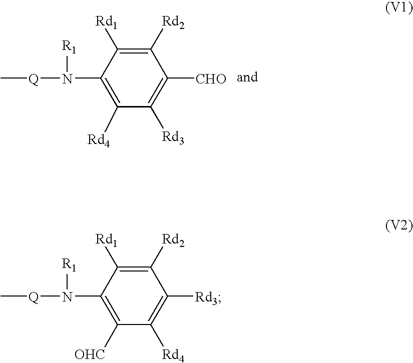

wherein each Q in (V1) and (V2) independently represents an alkylene group or a heteroalkylene group, the heteroalkylene group has one or more heteroatoms such as O and S; Rd₁-Rd₄ in (V1) and (V2) are each independently selected from the group consisting of hydrogen, linear and branched C₁-C₁₀ alkyl, C₄-C₁₀ aryl, and R₁ in (V1) and (V2) is C₁-C₁₀ alkyl (branched or linear). In some embodiments, Q in (V1) and (V2) may independently be an alkylene group represented by (CH₂)ₚ where p is in the range of about 2 to about 6. In some embodiments, R₁ in (V1) and (V2) is independently selected from a group consisting of methyl, ethyl, propyl, butyl, pentyl and hexyl. In an embodiment, Rd₁-Rd₄ in (V1) and (V2) are hydrogen.

In some embodiments, the polymerization method works under the same initial operating conditions as described above, and it also follows the same procedure to form the precursor polymer. After the precursor copolymer has been formed, it can be converted into the corresponding copolymer having non-linear optical groups and capabilities by a condensation reaction. In some embodiments, the condensation reagent may be selected from the group consisting of:

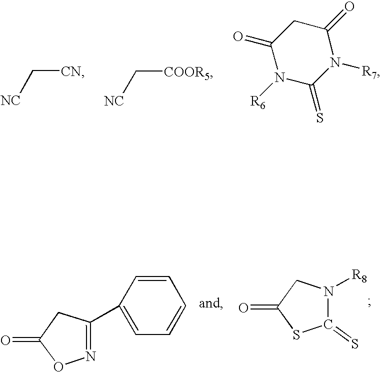

wherein R₅, R₆, R₇ and R₈ of the condensation reagents above are each independently selected from the group consisting of hydrogen, C₁-C₁₀ alkyl and C₄-C₁₀ aryl. The alkyl group may be either branched or linear.

In some embodiments, the condensation reaction can be carried out in the presence of a pyridine derivative catalyst at room temperature for about 1 to about 100 hrs. In some embodiments, a solvent, such as butyl acetate, chloroform, dichloromethylene, toluene or xylene, can also be used. In some embodiments, the reaction may be carried out without the catalyst at a solvent reflux temperature of 30° C. or above for about 1 to about 100 hours.

Other chromophores that possess non-linear optical properties in a polymer matrix are described in U.S. Pat. No. 5,064,264 (incorporated herein by reference) and may also be used in some embodiments. Additional suitable materials known in the art may also be used, and are well described in the literature, such as D. S. Chemla & J. Zyss, “Nonlinear Optical Properties of Organic Molecules and Crystals” (Academic Press, 1987). U.S. Pat. No. 6,090,332 describes fused ring bridge and ring locked chromophores that can form thermally stable photorefractive compositions, which may be useful as well. The chosen compound(s) is sometimes mixed in the copolymer in a concentration of about 1% to about 50% by weight.

In some embodiments, the composition further comprises an ingredient that provides additional non-linear optical functionality, the ingredient is represented by Formula (IIb):

D-B-A (IIb)

wherein D is an electron donor group; B is a π-conjugated group; and A is an electron acceptor group. In an embodiment, the ingredient that provides additional non-linear optical functionality is sensitive to a blue laser, thus configuring the composition to be photorefractive upon irradiation by a blue laser.

The term “electron donor” is defined as a group with low electron affinity when compared to the electron affinity of A. Non-limiting examples of electron donor include amino (NRz₁Rz₂), methyl (CH₃), oxy (ORz₁), phosphino (PRz₁Rz₂), silicate (SiRz₁), and thio (SRz₁), and Rz₁ and Rz₂ are organic substituents independently selected from alkenyls, alkyls, alkynyls, aryls, cycloalkenyls, cycloalkyls, and heteroaryls. In an embodiment, a heteroaryl has at least one heteroatom selected from O and S.

The term “π-conjugated group” is as defined above. In some embodiments, suitable π-conjugated groups include at least one of the following groups: aromatics and condensed aromatics, polyenes, polyynes, quinomethides, and corresponding heteroatom substitutions thereof (e.g. furan, pyridine, pyrrole, and thiophene). In some embodiments, suitable π-conjugated groups include at least one heteroatom replacement of a carbon in a C═C or C≡C bond and combinations thereof, with or without substitutions. In some embodiments, the suitable π-conjugated groups include no more than two of the preceding groups described in this paragraph. Further, said group or groups may be substituted with a carbocyclic or heterocyclic ring, condensed or appended to the π-conjugated group. Non-limiting examples of π-conjugated groups include:

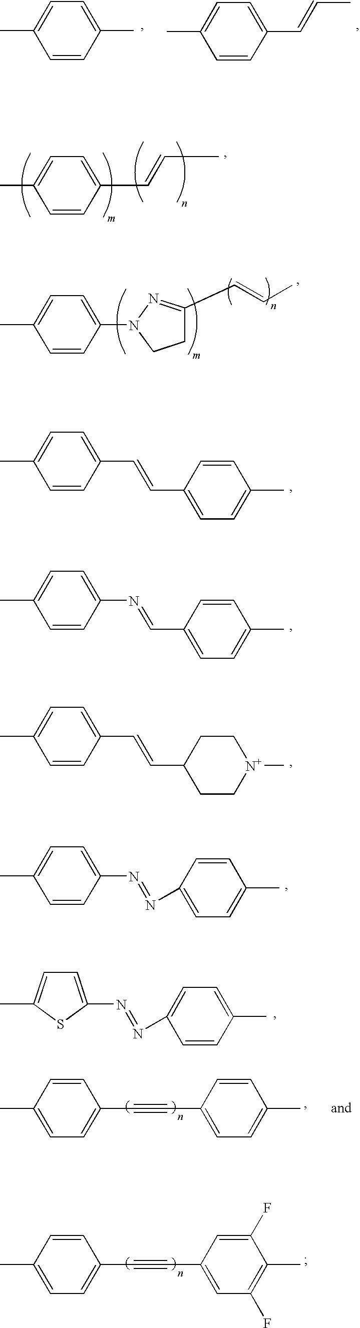

wherein m and n are each independently integers of 2 or less.

The term “electron acceptor” is defined above, and A is further defined as an electron acceptor group with high electron affinity when compared to the electron affinity of D. In some embodiments, A is selected from, but not limited to the following: amide; cyano; ester; formyl; ketone; nitro; nitroso; sulphone; sulphoxide; sulphonate ester; sulphonamide; phosphine oxide; phosphonate; N-pyridinium; hetero-substitutions in B; variants thereof; and other positively charged quaternary salts. In some embodiments, A is selected from the group consisting of: NO₂, CN, C═C(CN)₂, CF₃, F, Cl, Br, I, S(═O)₂CₙF₂ₙ₊₁, S(CₙF₂ₙ₊₁)═NSO₂CF₃; wherein n is an integer from 1 to 10.

In some embodiments, that at least one ingredient having formula (IIb) that provides additional non-linear optical functionality comprises a chromophore. Preferably, the chromophore is sensitive to a blue laser. In an embodiment, the chromophore is chosen from one or more of the following compounds:

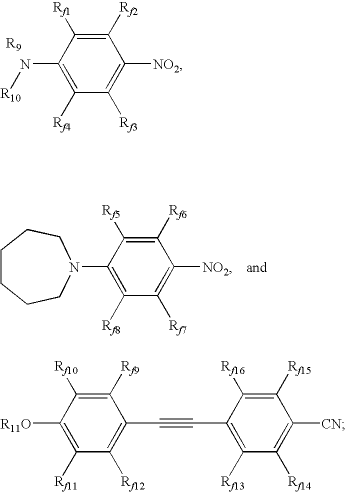

wherein each R₉-R₁₁ in the above compounds is independently selected from the group consisting of hydrogen, C₁-C₁₀ alkyl, and C₄-C₁₀ aryl, wherein the alkyl may be branched or linear, and wherein each Rf₁-Rf₁₄ is independently selected from H, F, and CF₃. The photorefractive composition comprising a polymer can be configured to be photorefractive upon irradiation by a blue laser by incorporating one or more ingredients having formula (IIb) that provides additional non-linear optical functionality. In an embodiment, the photorefractive composition comprising a polymer is configured to be photorefractive upon irradiation by a blue laser by incorporating one or more chromophores described herein. In an embodiment, the chromophore is 1-hexamethyleneimine-4-nitrobenzene, represented by the following structure:

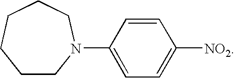

In some embodiments, the photorefractive composition further comprises a plasticizer. Any commercial plasticizer such as phthalate derivatives or low molecular weight hole transfer compounds (e.g., N-alkyl carbazole or triphenylamine derivatives or acetyl carbazole or triphenylamine derivatives) may be incorporated into the polymer matrix. A N-alkyl carbazole or triphenylamine derivative containing electron acceptor group is a suitable plasticizer that can help the photorefractive composition be more stable, as the plasticizer contains both N-alkyl carbazole or triphenylamine moiety and non-liner optical moiety in one compound.

Other non-limiting examples of the plasticizer include ethyl carbazole; 4-(N,N-diphenylamino)-phenylpropyl acatate; 4-(N,N-diphenylamino)-phenylmethyloxy acatate; N-(acetoxypropylphenyl)-N,N′,N′-triphenyl-(1,1′-biphenyl)-4,4′-diamine; N-(acetoxypropylphenyl)-N′-phenyl-N,N′-di(4-methylphenyl)-(1,1′-biphenyl)-4,4′-diamine; and N-(acetoxypropylphenyl)-N′-phenyl-N,N′-di(4-buthoxyphenyl)-(1,1′-biphenyl)-4,4′-diamine. Such compounds can be used singly or in mixtures of two or more monomers. Also, un-polymerized monomers can be low molecular weight hole transfer compounds, for example 4-(N,N-diphenylamino)-phenylpropyl (meth)acrylate; N-[(meth)acroyloxypropylphenyl]-N,N′, N′-triphenyl-(1,1′-biphenyl)-4,4′-diamine; N-[(meth)acroyloxypropylphenyl]-N′-phenyl-N,N′-di(4-methylphenyl)-(1,1′-biphenyl)-4,4′-diamine; and N-[(meth)acroyloxypropylphenyl]-N′-phenyl-N,N′-di(4-buthoxyphenyl)-(1,1′-biphenyl)-4,4′-diamine. Such monomers can be used singly or in mixtures of two or more monomers.

In some embodiments, a plasticizer may be selected from N-alkyl carbazole or triphenylamine derivatives:

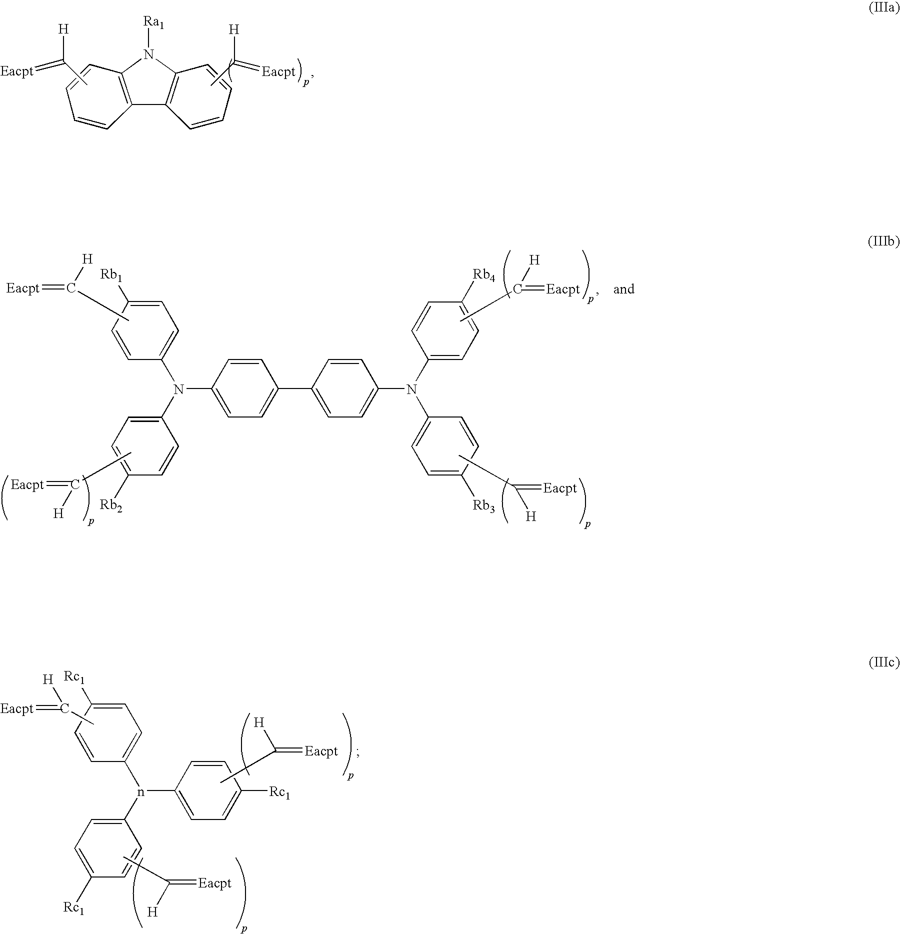

wherein Ra₁, Rb₁-Rb₄ and Rc₁-Rc₃ are each independently selected from the group consisting of hydrogen, branched and linear C₁-C₁₀ alkyl, and C₄-C₁₀ aryl; p is 0 or 1; Eacpt is an electron acceptor group and represented by a structure selected from the group consisting of the structures;

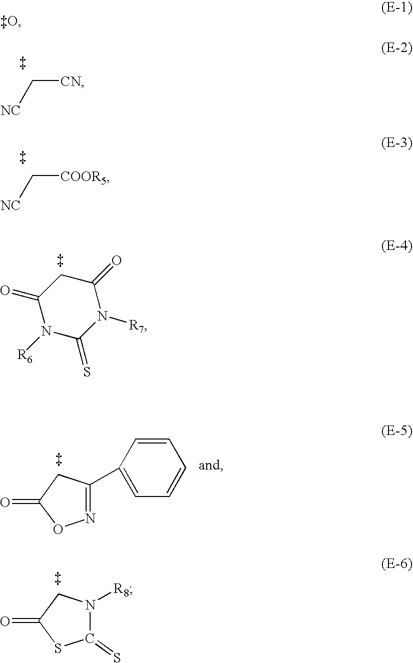

wherein R₅, R₆, R₇ and R₈ in formulas (E-3), (E-4) and (E-6) are each independently selected from the group consisting of hydrogen, linear and branched C₁-C₁₀ alkyl, and C₄-C₁₀ aryl.

In some embodiments, the photorefractive composition comprises a copolymer that provides photoconductive (charge transport) ability and non-linear optical ability. The photorefractive composition may also include other components as desired, such as sensitizer and/or plasticizer components. Some embodiments provide a photorefractive composition that comprises a copolymer. The copolymer may comprise a first repeating unit that includes a first moiety with charge transport ability, a second repeating unit including a second moiety with non-linear optical ability, and a third repeating unit that include a third moiety with plasticizing ability.

In addition, the ratio of different types of monomers used in forming the copolymer may be varied over a broad range. Some embodiments may provide a photorefractive composition with the first repeating unit (e.g., the repeating unit with charge transport ability) to the second repeating unit (e.g., the repeating unit with non-linear optical ability) weight ratio of about 100:1 to about 0.5:1, preferably about 10:1 to about 1:1. When the ratio of the first repeating unit to the second repeating unit is smaller than 0.5:1, the charge transport ability of copolymer may be relatively weak, and the response time may be undesirably slow to give good photorefractivity. However, even in this case, the addition of already described low molecular weight components having non-linear-optical ability can enhance photorefractivity. On the other hand, if the weight ratio is larger than 100:1s, the non-linear optical ability of copolymer itself is weak, and the diffraction efficiency tends to be too low to give good photorefractivity. However, even in this case, the addition of already described low molecular weight components having charge transport ability can enhance photorefractivity.

In some embodiments, the molecular weight and the glass transition temperature, Tg, of the copolymer are selected to provide desirable physical properties. In some embodiments, it is valuable and desirable, although not essential, that the polymer is capable of being formed into films, coatings and shaped bodies of various kinds by standard polymer processing techniques (e.g., solvent coating, injection molding or extrusion).

In some embodiments, the polymer has a weight average molecular weight, Mw, of from about 3,000 to about 500,000, preferably from about 5,000 to about 100,000. The term “weight average molecular weight” as used herein means the value determined by the GPC (gel permeation chromatography) method in polystyrene standards, as is well known in the art. In some embodiments, additional benefits may be provided by lowering the dependence on plasticizers. By selecting copolymers with intrinsically moderate Tg and by using methods that tend to depress the average Tg, it is possible to limit the amount of plasticizer required for the composition to no more than about 30% or 25%, and in some embodiments, no more than about 20%. In some embodiments, the photorefractive composition that can be activated by a blue laser may have a thickness of about 100 μm and a transmittance of higher than about 30%.

An embodiment provides a photorefractive composition that becomes photorefractive upon irradiation by a blue laser, wherein the photorefractive composition comprises a polymer comprising a first repeating unit that includes at least one moiety selected from the group consisting of the formulas (Ia), (Ib) and (Ic) as defined above. In some embodiments, the polymer may further comprise a second repeating unit comprising at least one moiety selected from formula (IIa) and chromophores. In some embodiments, the polymer may further comprise an ingredient selected from formula (IIb). In some embodiments, the polymer may further comprise a third repeating unit that includes at least one moiety selected from formulas (IIIa), (IIIb) and (IIIc). In an embodiment, an optical device comprises the photorefractive any one of the compositions described herein.

Another embodiment provides a method of modulating light, comprising irradiating a photorefractive compositions with blue laser, and activating photorefractive composition, thereby modulating light passing through the photorefractive composition. The photorefractive composition includes all embodiments discussed herein.

Many currently available photorefractive polymers have poor phase stabilities and can become hazy after days. Where the film composition comprising the photorefractive polymer shows haziness, poor photorefractive properties are exhibited. The haziness of the film composition usually comes from incompatibilities between several photorefractive components. For example, photorefractive compositions containing both charge transport ability components and non-linear optics ability components exhibit haziness because the components having charge transport ability are usually hydrophobic and non-polar, whereas components having non-linear optical ability are usually hydrophilic and polar. As a result, the natural tendency of the composition is to phase separate, thus causing haziness.

However, the embodiments presented herein show very good phase stability and gave no haziness, even after several months. The compositions described herein retain good photorefractive properties, as the compositions are very stable and exhibit little or no phase separation. Without being bound by theory, the stability is likely attributable to the chromophore structures and/or a mixture of various chromophores. In addition, the matrix polymer system is copolymer of components having charge transport ability and components having non-linear optics ability. That is, the components having charge transport ability and the components having non-linear optical ability coexist in one polymer chain, therefore rendering phase separation unlikely.

Furthermore, although heat usually increases the speed of phase separation, the compositions described herein exhibit good phase stability, even after being heated. For heat acceleration tests, the samples were typically heated to a temperature of between about 40 and about 120° C., preferably between about 60 and about 80° C. The heated samples were found to be stable after days, weeks and sometimes even after 6 months. The good phase stability allows the copolymer to be further process and incorporated into optical device applications for more commercial products.

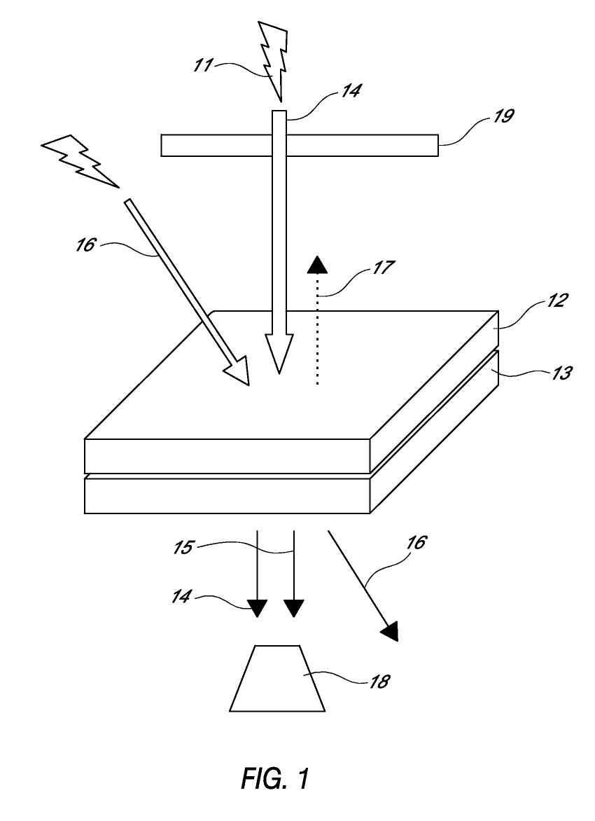

FIG. 1 is a schematic depiction illustrating a non-limiting embodiment of a hologram recording system with a photorefractive composition. Information may be recorded into the hologram medium, and the recorded information may be read out simultaneously. A laser source 11 may be used as to write information onto a recording medium 12. The recording medium 12 comprises the photorefractive polymer described herein and is positioned over a support material 13.

Laser beam irradiation of object beam 14 and reference beam 16 into the recording medium 12 causes interference grating, which generates internal electric fields and a refractive index change. Object beam 14 and reference beam 16 can project from various sides of the device other than those illustrated in FIG. 1. For example, instead of projecting from the same side of the recording medium 12, object beam 14 and reference beam 16 could project from opposite sides of the recording medium 12. Any type of angle between the object beam 14 and reference beam 16 can also be used. Multiple recordings are possible in the photorefractive composition of the recording medium 12 by changing the angle of the incident beam. The object beam 14 has a transmitted portion 15 of the beam and a refracted portion 17 of the beam.

An image display device 19 is set up parallel to the X-Y plane of the recording medium 12. Various types of image display devices may be employed. Some non-limiting examples of image display devices include a liquid crystal device, a Pockels Readout Optical Modulator, a Multichannel Spatial Modulator, a CCD liquid crystal device, an AO or EO modulation device, or an opto-magnetic device. On the other side of the recording medium 12, a read-out device 18 is also set up parallel to the X-Y plane of the recording medium 12. Suitable read-out devices include any kind of opto-electro converting devices, such as CCD, photo diode, photoreceptor, or photo multiplier tube.

In order to read out recorded information, the object beam 14 is shut out and only the reference beam 16, which is used for recording, is irradiated. A reconstructed image may be restored, and the reading device 18 is installed in the same direction as the transmitted portion 15 of the object beam and away from the reference beam 16. However, the position of the reading device 18 is not restricted to the positioning shown in FIG. 1. Recorded information in the photorefractive composition can be erased completely by whole surface light irradiation, or partially erased by laser beam irradiation.

The method can build the diffraction grating on the recording medium. This hologram device can be used not only for optical memory devices but also other applications, such as a hologram interferometer, a 3D holographic display, coherent image amplification applications, novelty filtering, self-phase conjugation, beam fanning limiter, signal processing, and image correlation, etc.

For the photorefractive device according to the invention, usually the thickness of a photorefractive layer is from about 10 μm to about 200 μm. Preferably, the thickness range is between about 30 μm and about 150 μm. If the sample thickness is less than 10 μm, the diffracted signal is not desired Bragg Refraction region, but Raman-Nathan Region which can not show proper grating behavior. On the other hand, if the sample thickness is greater than 200 μm, too high biased voltage would be required to show grating behavior. Also, composition transmittance for blue laser beams can be reduced significantly and result in no grating signals.

In some embodiments, the composition is configured to transmit 488 nm wave length laser beam. The composition transmittance depends on the photorefractive layer thickness, thus by controlling the thickness of the photorefractive layer comprising a photorefractive composition, the light modulating characteristics can be adjusted as desired. When the transmittance is low, the blue laser beam may not pass through the layer to form grating image and signals. On the other hand, if the absorbance is completely 0%, no laser energy can be absorbed to generate grating signals. In some embodiments, the suitable range of transmittance is between about 10% and about 99.99%, between about 30% and about 99.9%, and between about 40% and about 90%. Linear transmittance was performed to determine the absorption coefficient of the photorefractive device. For measurements, a photorefractive layer was exposed to a 488 nm laser beam with an incident path perpendicular to the layer surface. The beam intensity before and after passing through the photorefractive layer is monitored and the linear transmittance of the sample is given by:

$$T = {I}_{Transmitted} / {I}_{incident}$$

The wave length of blue laser is not really restricted, but usually a blue laser is defined as a laser which emits light wave-length of between 400 nm and 500 nm. Typically, as a blue laser light source, a widely available 488 nm laser can be used.

One of the many advantages of the photorefractive compositions described herein is a fast response time. Faster response times mean faster grating build-up, which enables the photorefractive composition to be used for wider applications, such as real-time hologram applications. Response time is the time needed to build up the diffraction grating in the photorefractive material when exposed to a laser writing beam. The response time of a sample of material may be measured by transient four-wave mixing (TFWM) experiments, as detailed in the Examples section below. The data may then be fitted with the following bi-exponential function:

η(t)=sin²{η₀(1−a₁e^{-t/J1}−a₂e^{-t/J2})}

with a₁+a₂=1; where η(t) is the diffraction efficiency at time t, η₀ is the steady-state diffraction efficiency, and J₁ and J₂ are the grating build-up times. The smaller number of J₁ and J₂ is defined as the response time.

Furthermore, the fast response time can be achieved without resorting to a very high electric field, such as a field in excess of about 100 V/μm (expressed as biased voltage). For the samples of the embodiments, a fast response times can generally be achieved at a biased voltage no higher than about 100 V/μm, including about 95 to about 50 V/μm, and about 90 to about 60 V/μm. The photorefractive compositions described herein have demonstrated a very fast response times of 0.24 seconds at 488 nm.

Another one of many advantages is the high diffraction efficiency, η. Diffraction efficiency is defined as the ratio of the intensity of a diffracted beam to the intensity of an incident probe beam, and is determined by measuring the intensities of the respective beams. The closer to 100% the ratio is, the more efficient is the device. In general, for a given photorefractive composition, a higher diffraction efficiency can be achieved by increasing the applied biased voltage. The samples of embodiments described herein could provide at least about 70% and even about 80% of the diffraction efficiency.

The embodiments are now further described by the following examples, which are intended to be illustrative of the invention, but are not intended to limit the scope or underlying principles in any way.

### Example 1

### (a) Monomers Containing Charge Transport Groups

N-[acroyloxypropoxyphenyl]-N,N′,N′-triphenyl-(1,1′-biphenyl)-4,4′-diamine (TPD acrylate) monomer was purchased from Fuji Chemical, Japan, and has the following structure:

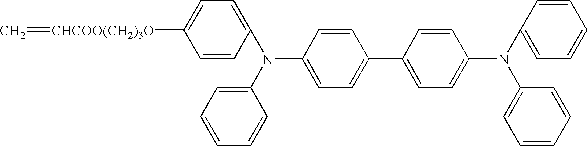

### (b) Monomers Containing Non-Linear Optical Groups

The non-linear optical precursor monomer 5-[N-ethyl-N-4-formylphenyl]amino-pentyl acrylate was synthesized according to the following synthesis scheme:

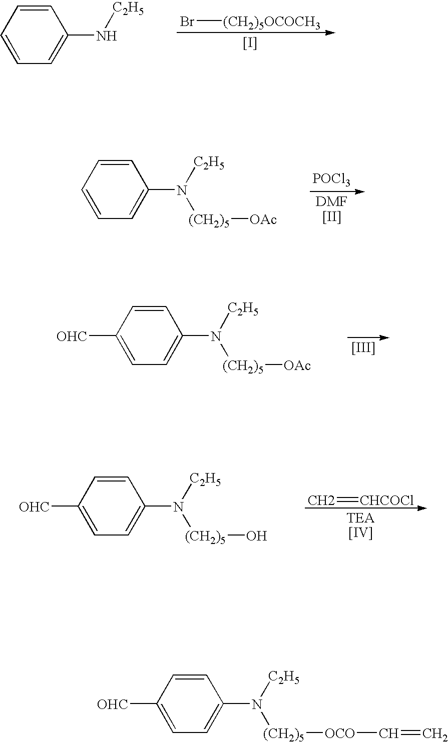

STEP I: Into bromopentyl acetate (5 mL, 30 mmol) and toluene (25 mL), triethylamine (4.2 mL, 30 mmol) and N-ethylaniline (4 mL, 30 mmol) were added at room temperature. This mixture was heated at 120° C. overnight. After cooling down, the reaction mixture was rotary-evaporated to form a residue. The residue was purified by silica gel chromatography (developing solvent: hexane/acetone=9/1). An oily amine compound was obtained. (Yield: 6.0 g (80%))

STEP II: Anhydrous DMF (6 mL, 77.5 mmol) was cooled in an ice-bath. Then, POCl₃ (2.3 mL, 24.5 mmol) was added dropwise into the cooled anhydrous DMF, and the mixture was allowed to come to room temperature. The amine compound (5.8 g, 23.3 mmol) was added through a rubber septum by syringe with dichloroethane. After stirring for 30 min., this reaction mixture was heated to 90° C. and the reaction was allowed to proceed overnight under an argon atmosphere.

After the overnight reaction, the reaction mixture was cooled and poured into brine water and extracted by ether. The ether layer was washed with potassium carbonate solution and dried over anhydrous magnesium sulfate. After removing the magnesium sulfate, the solvent was removed and the residue was purified by silica gel chromatography (developing solvent: hexane/ethyl acetate=3/1). An aldehyde compound was obtained. (Yield: 4.2 g (65%))

STEP III: The aldehyde compound (3.92 g, 14.1 mmol) was dissolved in methanol (20 mL). Into this solution, potassium carbonate (400 mg) and water (1 mL) were added at room temperature and the solution was stirred overnight. Next, the solution was poured into brine water and extracted by ether. The ether layer was dried over anhydrous magnesium sulfate. After removing the magnesium sulfate, the solvent was removed and the residue was purified by silica gel chromatography (developing solvent: hexane/acetone=1/1). An aldehyde alcohol compound was obtained. (Yield: 3.2 g (96%))

STEP IV: The aldehyde alcohol (5.8 g, 24.7 mmol) was dissolved in anhydrous THF (60 mL). Into this solution, triethylamine (3.8 mL, 27.1 mmol) was added and the solution was cooled by ice-bath. Acrolyl chloride (2.1 mL, 26.5 mmol) was added and the solution was maintained at 0° C. for 20 minutes. Thereafter, the solution was allowed to warm up to room temperature and stirred at room temperature for 1 hour, at which point TLC indicated that all of the alcohol compound had disappeared. The solution was poured into brine water and extracted by ether. The ether layer was dried over anhydrous magnesium sulfate. After removing the magnesium sulfate, the solvent was removed and the residue acrylate compound was purified by silica gel chromatography (developing solvent: hexane/acetone=1/1). The compound yield was 5.38 g (76%), and the compound purity was 99% (by GC).

### c) Synthesis of Non-Linear Optical Chromophore 7-FDCST

The non-linear optical precursor 7-FDCST (7 member ring dicyanostyrene, 4-homopiperidino-2-fluorobenzylidene malononitrile) was synthesized according to the following two-step synthesis scheme:

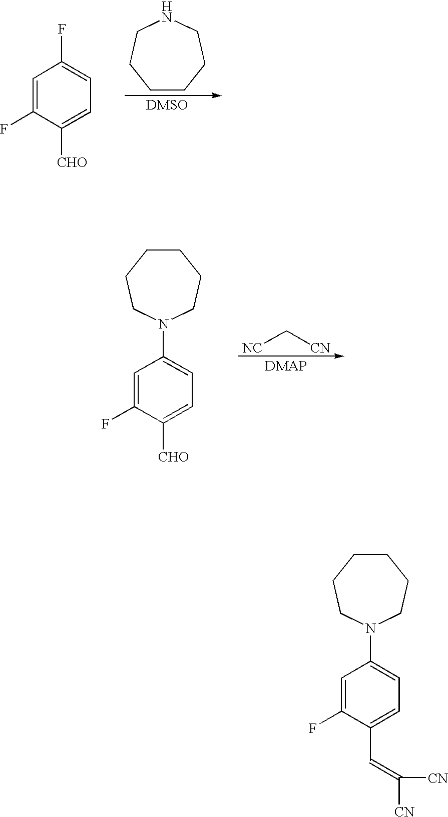

A mixture of 2,4-difluorobenzaldehyde (25 g, 176 mmol), homopiperidine (17.4 g, 176 mmol), lithium carbonate (65 g, 880 mmol), and DMSO (625 mL) was stirred at 50° C. for 16 hr. Water (50 mL) was added to the reaction mixture. The products were extracted with ether (100 mL). After removal of ether, the crude products were purified by silica gel column chromatography using hexanes-ethyl acetate (9:1) as eluent and crude intermediate was obtained (22.6 g). 4-(Dimethylamino)pyridine (230 mg) was added to a solution of the 4-homopiperidino-2-fluorobenzaldehyde (22.6 g, 102 mmol) and malononitrile (10.1 g, 153 mmol) in methanol (323 mL). The reaction mixture was kept at room temperature and the product was collected by filtration and purified by recrystallization from ethanol. The compound yield was 18.1 g (38%).

### d) Synthesis of Non-Linear Optical Chromophore 1-Hexamethyleneimine-4-Nitrobenzene

The non-linear-optical, blue laser sensitive, chromophore 1-hexamethyleneimine-4-nitrobenzene was synthesized according to the following synthesis scheme:

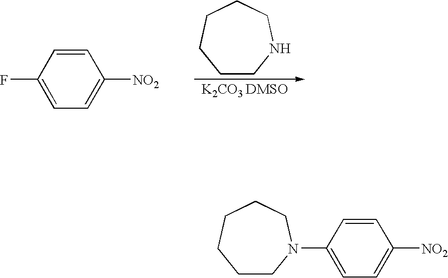

A mixture of 4-fluorobenzaldehyde (3 g, 21.26 mmol), homopiperidine (2.11 g, 21.26 mmol), lithium carbonate (3.53 g, 25.512 mmol), and DMSO (40 mL) was stirred at 50° C. for 16 hrs. Water (50 mL) was added to the reaction mixture. The products were extracted with ether (100 mL). After removal of ether, the crude products were recrystallized and yellow crystal was obtained. The compound yield was 4.45 g (95%).

### Example 2

### Preparation of TPD Acrylate Polymer by AIBN Radical Initiated Polymerization

The charge transport monomer N-[(meth)acroyloxypropylphenyl]-N,N′,N′-triphenyl-(1,1′-biphenyl)-4,4′-diamine (TPD acrylate) (61.50 g) was put into a three-necked flask. After toluene (400 mL) was added and purged by argon gas for 1 hour, azoisobutylnitrile (138 mg) was added into this solution. Then, the solution was heated to 65° C., while continuing to purge with argon gas.

After 18 hrs of polymerization, the polymer solution was diluted with toluene. The polymer was precipitated from the solution and added to methanol, then the resulting polymer precipitate was collected and washed in diethyl ether and methanol. The white polymer powder was collected and dried. The yield of polymer was 78%.

The weight average and number average molecular weights were measured by gel permeation chromatography, using polystyrene standard. The results were Mn=20,400, Mw=42,900, giving a polydispersity of 2.10.

### Example 3

### Preparation of TPD Acrylate/Chromophore Type 10:1 Copolymer by AIBN Radical Initiated Polymerization

The charge transport monomer N-[(meth)acroyloxypropylphenyl]-N,N′,N′-triphenyl-(1,1′-biphenyl)-4,4′-diamine (TPD acrylate) (43.34 g), and the non-linear optical precursor monomer 5-[N-ethyl-N-4-formylphenyl]amino-pentyl acrylate (4.35 g), prepared as described in Example 1, were put into a three-necked flask. After toluene (400 mL) was added and purged by argon gas for 1 hour, azoisobutylnitrile (118 mg) was added into this solution. Then, the solution was heated to 65° C., while continuing to purge with argon gas.

After 18 hrs of polymerization, the polymer solution was diluted with toluene. The polymer was precipitated from the solution and added to methanol, then the resulting polymer precipitate was collected and washed in diethyl ether and methanol. The white polymer powder was collected and dried. The yield of polymer was 66%.

The weight average and number average molecular weights were measured by gel permeation chromatography, using polystyrene standard. The results were Mn=10,600, Mw=17,100, giving a polydispersity of 1.61.

### Example 4

### Preparation of TPD Acrylate/CbZ Acrylate/Chromophore Type 5:5:1 Copolymer by AIBN Radical Initiated Polymerization

The charge transport monomer N-[(meth)acroyloxypropylphenyl]-N,N′,N′-triphenyl-(1,1′-biphenyl)-4,4′-diamine (TPD acrylate) (5.0 g), N-[(meth)acroyloxypropylphenyl]-N,N′-diphenylamine (CBz acrylate) (5.0 g), and the non-linear optical precursor monomer 5-[N-ethyl-N-4-formylphenyl]amino-pentyl acrylate (1.0 g), prepared as described in Example 1, were put into a three-necked flask. After toluene (85 mL) was added and purged by argon gas for 1 hour, azoisobutylnitrile (47 mg) was added into this solution. Then, the solution was heated to 65° C., while continuing to purge with argon gas.

After 18 hrs of polymerization, the polymer solution was diluted with toluene. The polymer was precipitated from the solution and added to methanol, then the resulting polymer precipitate was collected and washed in diethyl ether and methanol. The white polymer powder was collected and dried. The yield of polymer was about 84%.

The weight average and number average molecular weights were measured by gel permeation chromatography, using polystyrene standard. The results were Mn=12,300, Mw=27,700, giving a polydispersity of 2.25.

### Example 5

### Preparation of Photorefractive Composition

A photorefractive composition testing sample was prepared. The components of the composition were as follows:

| | |
|---|---|
| (i) TPD charge transport (described in Production Example 1): | 50.0 wt % |
| (ii) Prepared chromophore of 1-hexamethyleneimine-4- | 30.0 wt % |
| nitrobenzene: | |
| (iii) 9-ethylcarbazole plasticizer: | 20.0 wt % |

To prepare the composition, the components listed above were dissolved in toluene and stirred overnight at room temperature. After removing the solvent by rotary evaporator and vacuum pump, the residue was scratched and gathered.

To make testing samples, this powdery residue mixture was put on a glass slide and melted at 125° C. to make a film with a thickness of 200-300 μm, or pre-cake. Small portions of this pre-cake were taken off and sandwiched between indium tin oxide (ITO) coated glass plates separated by a 50 μm spacer to form the individual samples.

### Measurement 1: Diffraction Efficiency

The diffraction efficiency was measured at 488 nm by four-wave mixing experiments. Steady-state and transient four-wave mixing experiments were done using two writing beams making an angle of 20.5 degree in air; with the bisector of the writing beams making an angle of 60 degree relative to the sample normal.

For the four-wave mixing experiments, two s-polarized writing beams with equal intensity of 0.2 W/cm² in the sample were used; the spot diameter was 600 μm. A p-polarized beam of 1.7 mW/cm² counter propagating with respect to the writing beam nearest to the surface normal was used to probe the diffraction gratings; the spot diameter of the probe beam in the sample was 500 μm. The diffracted and the transmitted probe beam intensities were monitored to determine the diffraction efficiency. Then, we defined this diffraction efficiency as

### Measurement 2: Rising Time (Response Time)

The diffraction efficiency was measured as a function of the applied field, using a procedure similar to that described in Measurement 1, by four-wave mixing experiments at 488 nm with s-polarized writing beams and a p-polarized probe beam. The angle between the bisector of the two writing beams and the sample normal was 60 degree and the angle between the writing beams was adjusted to provide a 2.5 μm grating spacing in the material (˜20 degree). The writing beams had equal optical powers of 0.45 mW/cm², leading to a total optical power of 1.5 mW on the polymer, after correction for reflection losses. The beams were collimated to a spot size of approximately 500 μm. The optical power of the probe was 100 μW. The measurement of the grating buildup time was done as follows: certain electric field (V/μm) was applied to the sample, and the sample was illuminated with two writing beams and the probe beam for 100 ms. Then, the evolution of the diffracted beam was recorded. The response time (rising time) was estimated as the time required to reach e⁻¹ of steady-state diffraction efficiency.

### Measurement 3: Erasing Time

The diffraction efficiency was measured as a function of the applied field, using a procedure similar to that described in Measurement 1, by four-wave mixing experiments at 488 nm with s-polarized writing beams and a p-polarized probe beam. The angle between the bisector of the two writing beams and the sample normal was 60 degree and the angle between the writing beams was adjusted to provide a 2.5 μm grating spacing in the material (˜20 degree). The writing beams had equal optical powers of 0.45 mW/cm², leading to a total optical power of 1.5 mW on the polymer, after correction for reflection losses. The beams were collimated to a spot size of approximately 500 μm. The optical power of the probe was 100 μW. The measurement of the grating erasing time was done as follows: certain electric field (V/μm) was applied to the sample, and the sample was exposed to both two writing beams until the diffraction efficiency reach the steady state. Then one of the writing beams was blocked and the evolution of the diffracted beam was recorded. The erasing time was estimated as the time required to erase e⁻¹ of steady-state diffraction efficiency.

Obtained performance:

| Initial diffraction efficiency (%): | 80% at 80 V/μm |
|---|---|
| Response time: | 0.25 (s) at 80 V/μm |
| Erasing time: | 0.67 (s) at 80 V/μm |
| Transmittance at 488 nm: | 39% |

### Example 6

A photorefractive composition testing sample was prepared. The components of the composition were as follows:

| | |
|---|---|
| (i) TPD/DCST charge transport (described in Production | 50.0 wt % |
| Example 2): | |
| (ii) Prepared chromophore of 1-hexamethyleneimine-4- | 30.0 wt % |
| nitrobenzene: | |
| (iii) 9-ethylcarbazole: | 20.0 wt % |

Obtained performance:

| Initial diffraction efficiency (%): | 80% at 65 V/μm |
|---|---|
| Response time: | 0.24 (s) at 65 V/μm |
| Erasing time: | 0.75 (s) at 65 V/μm |
| Transmittance at 488 nm: | 40% |

### Example 7

A photorefractive composition testing sample was prepared. The components of the composition were as follows:

| | |
|---|---|
| (i) TPD/Cbz/DCST charge transport (described in Production | 50.0 wt % |
| Example 3): | |
| (ii) Prepared chromophore of 1-hexamethyleneimine-4- | 30.0 wt % |
| nitrobenzene: | |
| (iii) 9-ethylcarbazole: | 20.0 wt % |

Obtained performance:

| Initial diffraction efficiency (%): | 80% at 70 V/μm |
|---|---|
| Response time: | 0.98 (s) at 70 V/μm |
| Erasing time: | 3.05 (s) at 70 V/μm |
| Transmittance at 488 nm: | 33% |

### Comparative Example

A photorefractive composition was obtained in the same manner as in the Example 1 except composition components. The components of the composition were as follows:

| | |
|---|---|
| (i) TPD charge transport (described in Production Example 1): | 50.0 wt % |
| (ii) Prepared chromophore of 7-FDCST: | 30.0 wt % |
| (iii) 9-ethylcarbazole: | 20.0 wt % |

Obtained performance:

| | |
|---|---|
| Initial diffraction efficiency (%): | no signal |
| Response time: | no signal |
| Erasing time: | no signal |
| Transmittance at 488 nm: | less than 1% |

As shown in this comparative data which is described in the prior art, no grating formation ability was observed because the composition is too dark for the 488 nm laser beam. Good diffraction efficiency was only observed when irradiated by 633 nm red laser beams.

All literature references and patents mentioned herein are hereby incorporated in their entireties. Although the foregoing invention has been described in terms of certain preferred embodiments, other embodiments will become apparent to those of ordinary skill in the art in view of the disclosure herein without departing from the scope of the invention. Accordingly, all such modifications and changes are intended to fall within the scope of the invention, as defined by the appended claims.

What is claimed is:

1. A composition configured to be photorefractive upon irradiation by a blue laser, wherein the composition comprises a polymer comprising a repeating unit that includes at least one moiety selected from the group consisting of the following formulas: 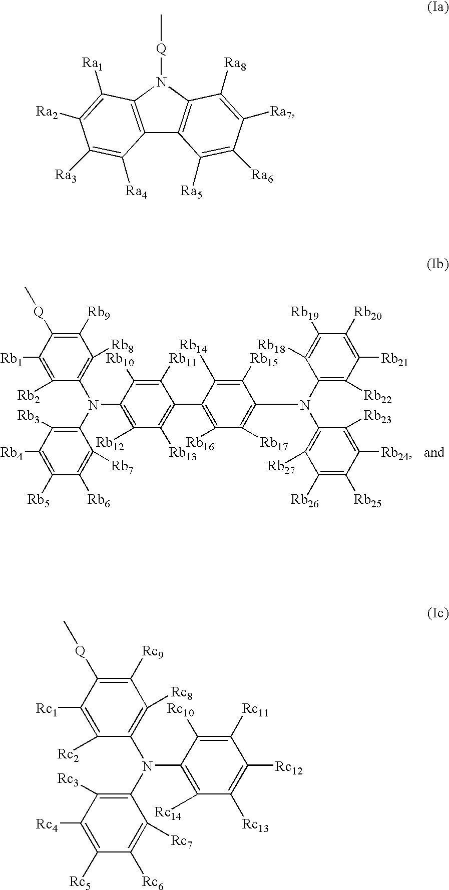
wherein each Q in formulas (Ia), (Ib) and (Ic) independently represents an alkylene group or a heteroalkylene group, Ra₁-Ra₈, Rb₁-Rb₂₇ and Rc₁-Rc₁₄ in (Ia), (Ib), and (Ic) are each independently selected from the group consisting of hydrogen, C₁-C₁₀ alkyl, and C₄-C₁₀ aryl, wherein the C₁-C₁₀ alkyl may be linear or branched.

2. The composition of claim 1, wherein the polymer further comprises a second repeating unit that includes a moiety represented by the following formula: 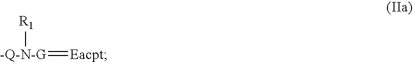
wherein Q in formula (IIa) represents an alkylene group or a heteroalkylene group; R₁ in formula (IIa) is selected from the group consisting of hydrogen, linear C₁-C₁₀ alkyl, branched C₁-C₁₀ alkyl and C₄-C₁₀ aryl; G in formula (IIa) is a π-conjugated group; and Except in formula (IIa) is an electron acceptor group.

3. The composition of claim 2, wherein the second repeating unit is represented by the following formula: 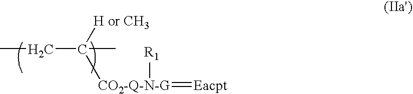
wherein Q in formula (IIa′) represents an alkylene group or a heteroalkylene group; R₁ in formula (IIa′) is selected from the group consisting of hydrogen, linear C₁-C₁₀ alkyl, branched C₁-C₁₀ alkyl, and C₄-C₁₀ aryl; G in formula (IIa′) is π-conjugated group; and Eacpt in formula (IIa′) is an electron acceptor group.

4. The composition of claim 2, wherein G in formulas (IIa) and (IIa′) is represented by a structure selected from the group consisting of the following formulas: 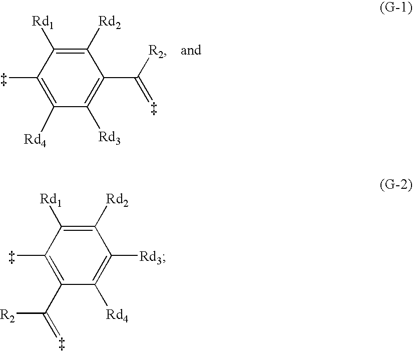
wherein Rd₁-Rd₄ in (G-1) and (G-2) are each independently selected from the group consisting of hydrogen, linear C₁-C₁₀ alkyl, branched C₁-C₁₀ alkyl, C₄-C₁₀ aryl, and halogen; and R₂ in (G-1) and (G-2) is independently selected from the group consisting of hydrogen, linear C₁-C₁₀ alkyl, branched C₁-C₁₀ alkyl, and C₄-C₁₀ aryl.

5. The composition of claim 2, wherein Eacpt in formulas (Ia) and (IIa′) is represented by a structure selected from the group consisting of the following formulas: 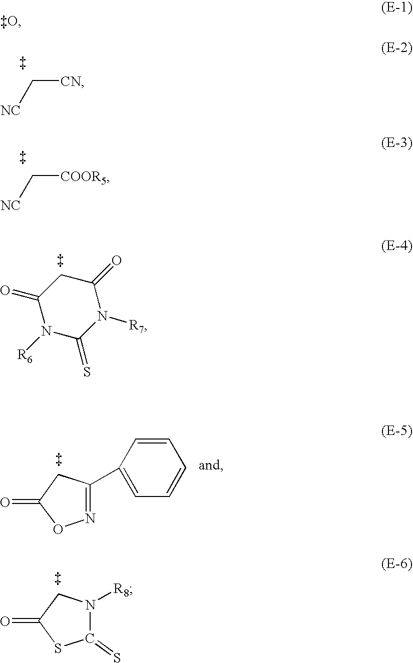
wherein R₅, R₆, R₇ and R₈ in formulas (E-3), (E-4), and (E-6) are each independently selected from the group consisting of hydrogen, linear C₁-C₁₀ alkyl, branched C₁-C₁₀ alkyl, and C₄-C₁₀ aryl.

6. The composition of claim 1, wherein the composition further comprising an ingredient that provides additional non-linear optical functionality represented by the following formula:
D-B-A (IIb);
wherein the ingredient providing additional non-linear optical functionality is sensitive to a blue laser; and
wherein D in formula (IIb) is an electron donor group, B in formula (IIb) is a π-conjugated group, and A in formula (IIb) is an electron acceptor group.

7. The composition of claim 6, wherein the electron donor group in D is selected from NRz₁, Rz₂, CH₃, ORz₁, PRz₁Rz₂, SiRz₁, and SRz₁; and wherein Rz₁ and Rz₂ are independently selected from alkenyls, alkyls, alkynyls, aryls, cycloalkenyls, cycloalkyls, and heteroaryls.

8. The composition of claim 6, wherein B is selected from no more than two of the group consisting of an aromatic ring group, a polyene group, a polyyne group, a quinomethide group, combinations thereof, and variations of such groups containing heteroatoms wherein at least one carbon and/or at least one C═C or C≡C bond is replaced by a heteroatom.

9. The composition of claim 6, wherein B is selected from one or more of the following moieties:

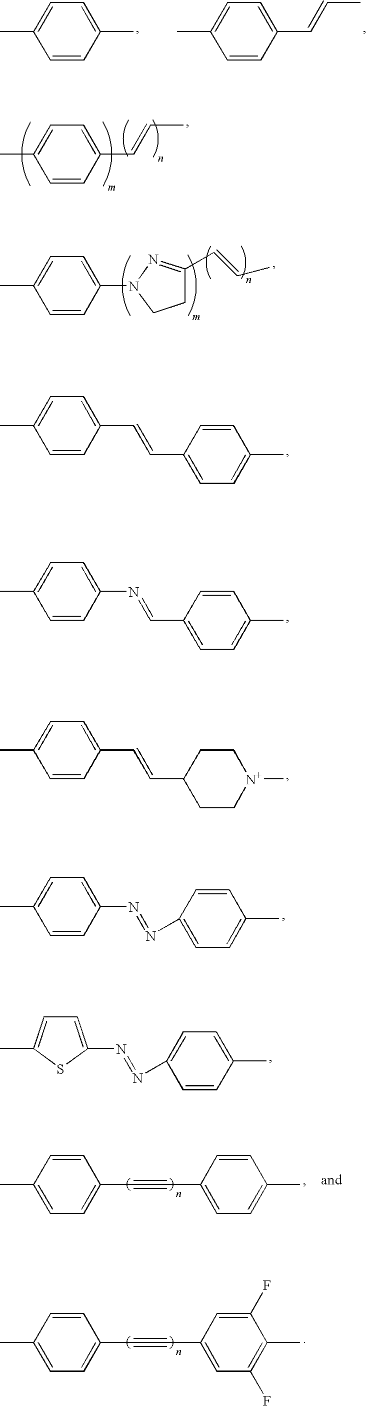

10. The composition of claim 6, wherein the electron acceptor group in A is selected from NO₂, CN, C═C(CN)₂, CF₃, F, Cl, Br, I, S(═O)₂CₙF₂ₙ₊₁, S(CₙF₂ₙ₊₁)═NSO₂CF₃; and wherein n is an integer from 1 to 10.

11. The composition of claim 6, wherein the ingredient that provides additional non-linear optical functionality comprises a chromophore.

12. The composition of claim 11, wherein the chromophore is selected from one of the following formulas: 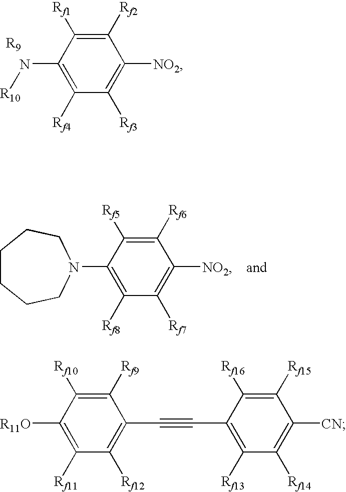
wherein R₉-R₁₁ in the above compounds is selected from the group consisting of hydrogen, C₁-C₁₀ alkyl, and C₄-C₁₀ aryl; wherein C₁-C₁₀ alkyl may be branched or linear; and Rf₁-Rf₁₄ in the above compounds is independently selected from H, F, and CF₃.

13. The composition of claim 1, wherein the composition further comprises a plasticizer and/or sensitizer.

14. The composition of claim 13, wherein the plasticizer is selected from N-alkyl carbazole and triphenylamine derivatives.

15. The composition of claim 13, wherein the plasticizer is selected from the following formulas: 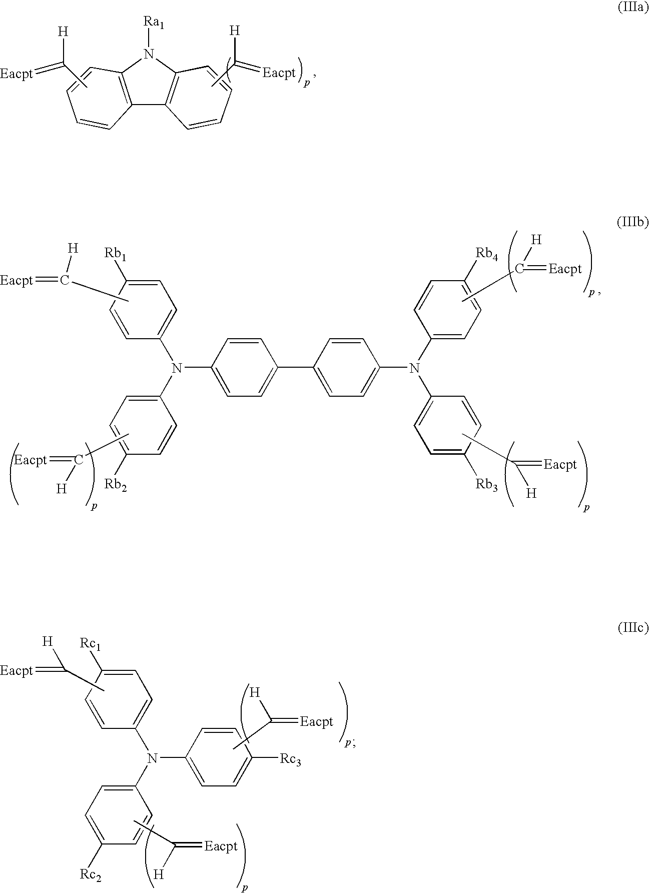
wherein Ra₁, Rb₁-Rb₄ and Rc₁-Rc₃ in formulas (IIIa), (IIIb), and (IIIc) are each independently selected from the group consisting of hydrogen, linear C₁-C₁₀ alkyl, branched C₁-C₁₀ alkyl and C₄-C₁₀ aryl; p is 0 or 1; and Eacpt formulas (IIIa), (IIIb), and (IIIc) is an electron acceptor group.

16. The composition of claim 1, wherein the polymer comprises a repeating unit selected from the group consisting of the following formulas: 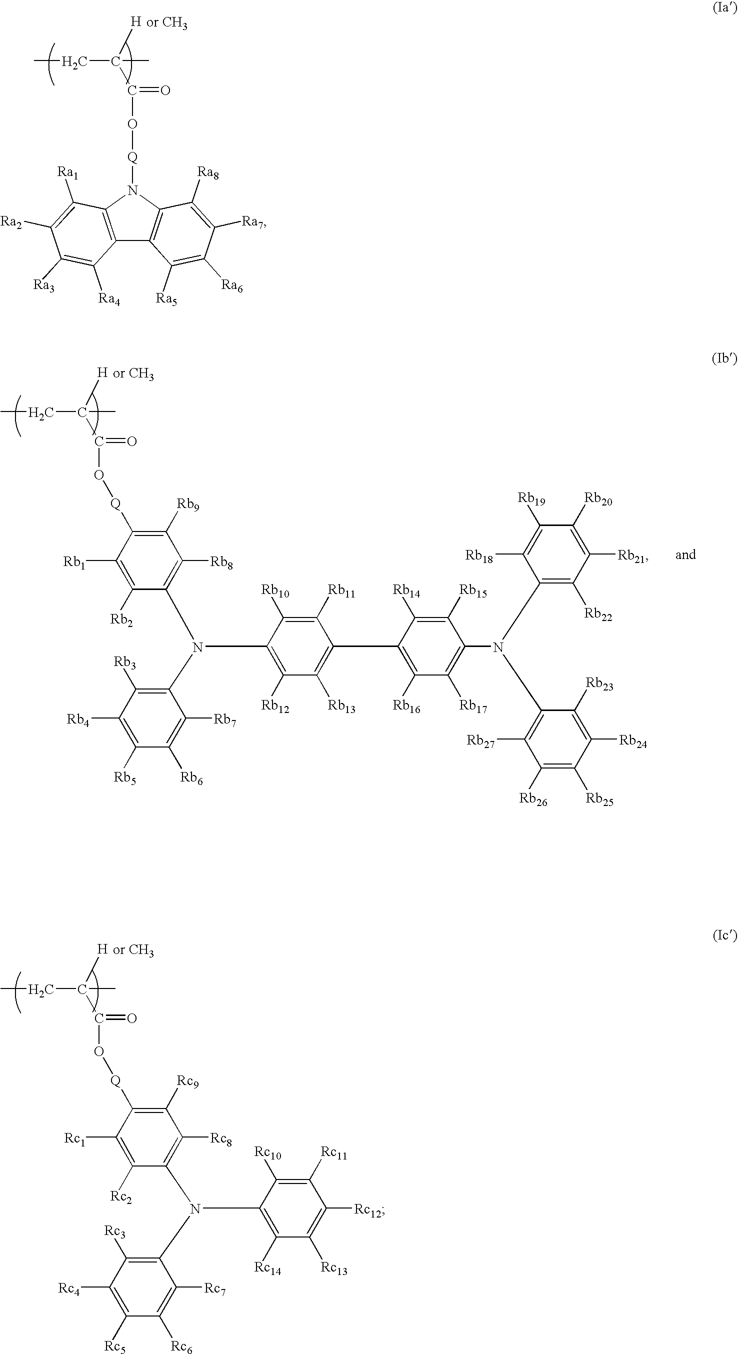
wherein each Q in formulas (Ia′), (Ib′) and (Ic′) independently represents an alkylene group or a heteroalkylene group; Ra₁-Ra₈, Rb₁-Rb₂₇ and Rc₁-Rc₁₄ in formulas (Ia′), (Ib′) and (Ic′) are each independently selected from the group consisting of hydrogen, C₁-C₁₀ alkyl, and C₄-C₁₀ aryl, wherein the alkyl can be either branched or linear.

17. The composition of claim 1, wherein the composition has a transmittance of higher than about 30% at a thickness of 100 μm when irradiated by a blue laser.

18. The composition of claim 1, wherein the composition is configured to be photorefractive upon irradiation by a blue laser at a wavelength of 488 nm.

19. An optical device that comprises the composition according to claim 1.

20. A method for modulating light, comprising the steps of:
providing a photorefractive composition comprising a polymer, wherein the polymer comprises a repeating unit that includes a moiety selected from the group consisting of the following structures: 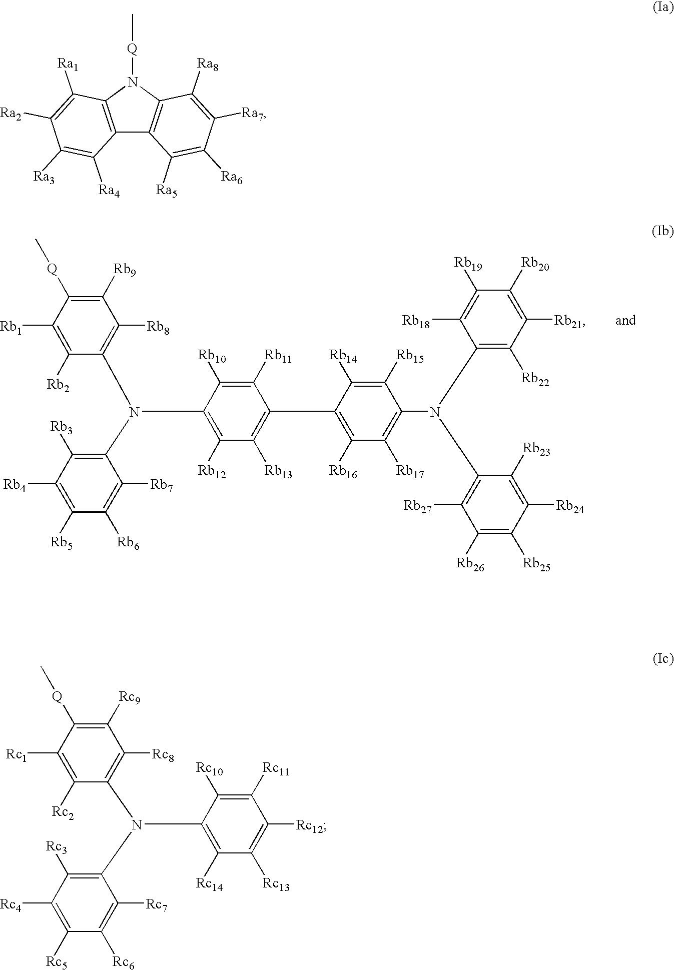
wherein each Q in formulas (Ia), (Ib) and (Ic) independently represents an alkylene or a heteroalkylene, Ra₁-Ra₈, Rb₁-Rb₂₇ and Rc₁-Rc₁₄ in (Ia), (Ib), and (Ic) are each independently selected from the group consisting of hydrogen, C₁-C₁₀ alkyl, and C₄-C₁₀ aryl, wherein the C₁-C₁₀ alkyl may be linear or branched; and
irradiating the photorefractive composition with a blue laser to thereby modulate a photorefractive property of the composition.
